(19) United States
(12) Patent Application Publication
(10) Pub. No.: US 2015/0051866 A1
(43) Pub. Date: Feb. 19, 2015

(54) METHOD FOR OPTIMIZING PHASOR MEASUREMENT UNIT PLACEMENT

(71) Applicant: National Tsing Hua University, Hsinchu (TW)

(72) Inventors: Chia-Chi CHU, Hsinchu (TW); Tsung-Jung HSIEH, Tainan (TW); Jian-Hong LIU, Hsinchu (TW); Xian-Chang Guo, Hsinchu (TW)

(73) Assignee: National Tsing Hua University, Hsinchu (TW)

(21) Appl. No.: 14/070,302

(22) Filed: Nov. 1, 2013

(30) Foreign Application Priority Data
Aug. 13, 2013 (TW) 102128993

(51) Int. Cl. G01R 21/00

(52) U.S. Cl. CPC G01R 21/00
USPC 702/150

(57) ABSTRACT

A method for optimizing phasor measurement unit placement includes two phase, calculating a degree of each node of a power system; selecting a node with maximum degree as a center and propagate to the entire power system so as to form a spanning tree; selecting a feasible power dominating set (PDS) of minimum cardinality for the spanning tree in the Phase I. In phase II, use the Artificial Bees Colony Algorithm. According to the minimum PDS, calculating a fitness functions by the equation

$${fit}_{i} = \{ \begin{matrix}1 \text{/} \vert {f}_{i} \vert + 1 , {f}_{i} < 0 \\ {f}_{i} , {f}_{i} \geq 0\end{matrix} ;$$

generating a nearby solution randomly through Vᵢⱼ=Xᵢⱼ+μ(X_{if}−Xₖⱼ); and select a better solution by using greedy search and probability search by the equation

$${P}_{h} = {fit}_{i} \text{/} {\sum }_{j = 1}^{SN} {fit}_{i} ;$$

abandoning the current solution as not even improving the solution in the given time of the iteration number and generating a new solution randomly Xₕ^{j}=Xₘᵢₙ^{j}+rand[1,0](Xₘₐₓ^{j}−Xₘᵢₙ^{j}) in order to prevent a local optimum. The vest solution will be hold until meeting the termination condition.

### TECHNICAL FIELD

The present invention relates to a caculating method, more especially a method for optimizing phasor measurement unit placement.

### BACKGROUND

Phasor measurement units (PMUs) are devices offering advanced monitoring, analysis, control, and protections in modern smart grid applications using global positioning satellite systems (GPS). The pioneering work on PMU development and utilization, which introduced the concept of synchronized phasor estimation coupled with the computer-based measurement technique and many applications of PMUs. The capability of PMUs makes significant improvements in the accuracy and robustness of state estimations. Especially when feeding such accurate and on-line information provided by PMUs into the modern energy management systems (EMS), power system operators can quickly outlook entire systems' dynamics. The ability of situational awareness can be significantly improved. Based on modern development of GPS, the common time reference of PMUs with the GPS signal for synchronizing voltage and current measurement can offer an accuracy of less than 1 μs. Exploiting the ability of PMUs placed at electric buses leads to high-precision measurement of voltage and current phasors.

With the growing number of PMUs planned for installation in the near future, including the limitations of cost and communication facilities, there is pressing need for utilities and research institutes to look for the best solutions to PMU placements. Therefore, the optimal PMU placement (OPP) problem is formulated as to find the minimum number of PMUs such that the entire system is completely observable. This challenge of selecting an appropriate placement of PMUs can be considered a combinatorial optimization problem which has been proved to be NP-complete even when restricted to some special classes of power networks.

In the past few decades, various algorithms have been proposed for this OPP problem. Roughly speaking, three distinct categories can be classified: (i) graph-based algorithms, (ii) meta-heuristic algorithms, and (iii) mathematical programmings. In graph-based algorithms, the problem of locating the smallest set of PMUs required to observe all the states of the power system is closely related to the famous vertex cover problem and the power domination (PD) problem. Under this framework, the NP-completeness proofs and theoretic upper bound have been investigated. Polynomial time algorithms have been studied for special graphs such as trees, interval graphs, and circular-arc graphs. In addition, several approximation algorithms for general graphs have also be conducted independently. In more recent trends, some restricted constraints, such as fault-tolerant measurements and propagation time-constraint problem, are also been explored. The idea behind those graph-based approaches is to exploit the decomposition technique in graph theory. Since most practical large-scale power systems possess sparse properties, such decomposition techniques can be directly applied to power networks. Thus, the possible location of PMUs can be quickly identified on a decomposition structure.

Meta-heuristic methods, which are based on intelligent search processes, have also been widely applied to this problem. GA-based procedures such as the non-dominated sorting genetic algorithm and the immunity genetic algorithm for solving the PMU placement were proposed. However, such meta-heuristic methods cannot prove optimally as in deterministic methods and had low solving efficiency; such obstacles restrict their applications to practical large-scale power systems.

The major disadvantage of the mathematical programmings approach is related to the solution quality. Even though the NP-hard problem can be formulated, relaxation techniques for obtaining approximate solutions are always employed in order to develop solution algorithms. Under this framework, the integrality gap, which is defined as the maximum ratio between the solution quality of the integer program and of its relaxation problem, will be an important index to ensure the solution quality. However, the linear programming relaxation for this OPP problem has a big integrality gap.

### SUMMARY

One of the purposes of the invention is to disclose a method for optimizing placement of phasor measurement unit, comprising: calculating a degree of a plurality of nodes of a power system; selecting a node with a maximum degree as a center, and propagating through adjacent nodes from said center to form a spanning tree; finding a feasible power dominating set of minimum cardinality for said spanning tree; evaluating a fitness function by a equation

$${fit}_{i} = \{ \begin{matrix}1 \text{/} \vert {f}_{i} \vert + 1 , {f}_{i} < 0 \\ {f}_{i} , {f}_{i} \geq 0\end{matrix}$$

according to said feasible power dominating set; generating a solution by a equation Vᵢⱼ=Xᵢⱼ+μ(Xᵢⱼ−Xₖⱼ); calculating a probability by a equation

$${P}_{h} = {fit}_{i} \text{/} {\sum }_{j = 1}^{SN} {fit}_{i} ;$$

and selecting a best solution based on said probability via a greedy search.

### BRIEF DESCRIPTION OF THE DRAWINGS

Features and advantages of embodiments of the subject matter will become apparent as the following detailed description proceeds, and upon reference to the drawings, wherein like numerals depict like parts, and in which:

FIG. 1 illustrates a flow chart of the PMU replacement selection method in accordance with an embodiment of the present invention.

FIG. 2A to FIG. 2D illustrate an IEEE 57 bus system with a plurality of nodes.

### DETAILED DESCRIPTION

Reference will now be made in detail to the embodiments of the present invention. While the invention will be described in conjunction with these embodiments, it will be understood that they are not intended to limit the invention to these embodiments. On the contrary, the invention is intended to cover alternatives, modifications and equivalents, which may be included within the spirit and scope of the invention.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

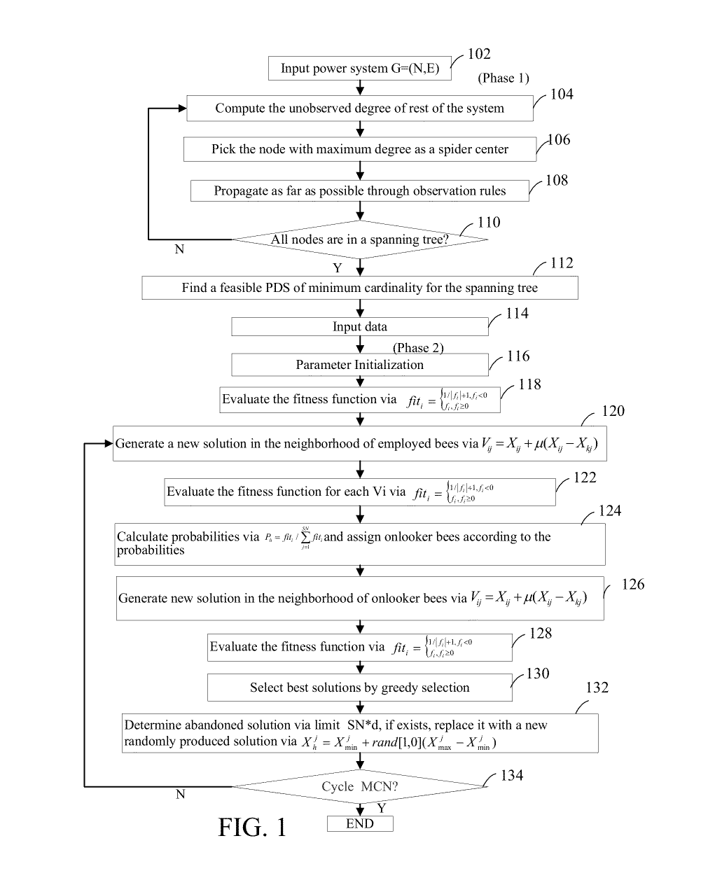

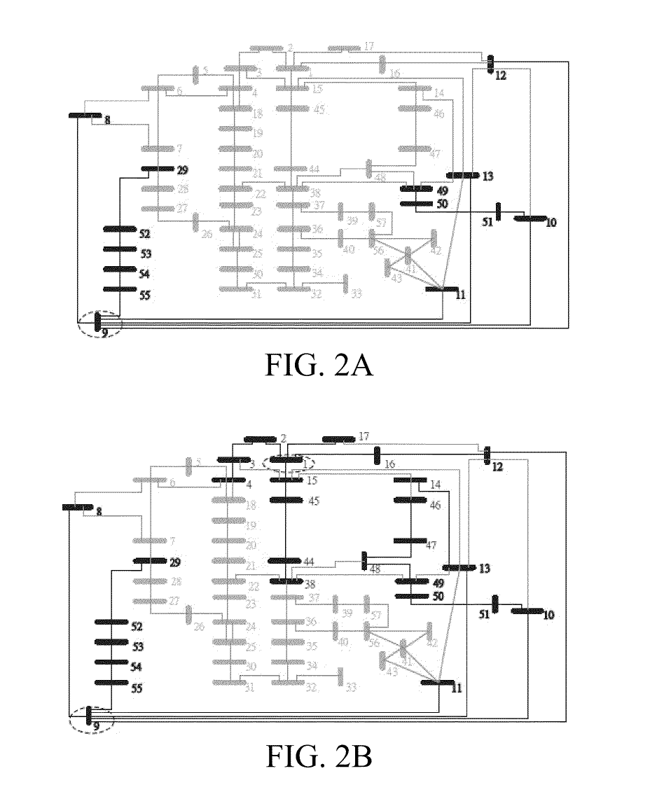

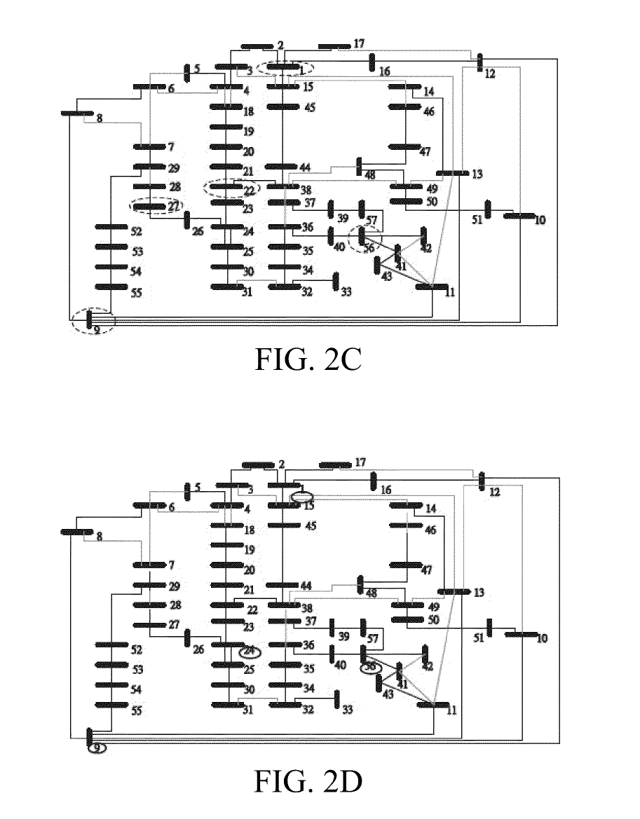

FIG. 1 illustrates a flow chart of the PMU replacement selection method in accordance with an embodiment of the present invention. FIG. 1 will be described with FIG. 2A to FIG. 2D. In block 102, inputting a power system in Phase 1. In one embodiment, letting the power system G=(N,E) be a graph representation of a power grid in which a node in N represents a bus location and an edge in E represents a transmission line joining two buses. A graph representation of a power system is sparse if the number of edges is a constant times the number of nodes, that is, |E|=c*|N|, for a constant c.

In block 104, computing the degree of the unobserved neighbors of the power system G. In one embodiment, the construction of a spanning tree via the SD-like technique on IEEE 57-bus system is illustrated in FIG. 2A to FIG. 2D. In block 106, selecting a node has the maximum degree of unobserved neighbors as a spider center. In one embodiment, node 9 is selected as the first spider center since it has the maximum degree of unobserved neighbors. Then, in block 108, the spider center, node 9, can propagates through adjacent nodes by applying observation rules and forms a spider P{v9}, as shown in FIG. 2A. The unobserved degree of each remaining node in the system is updated, and the next node with the maximum unobserved degree is node 1, as shown in FIG. 2B. In block 110, the similar procedure repeatedly performs until all nodes in G are contained in the union of these spiders, which forms a spanning tree T. FIG. 2c shows that the union of the spiders P{v9,v1,v56,v22,v27} derived by their centers 9, 1, 56, 22 and 27 constructs the spanning tree T. Note that the feasible PDS for the spanning tree T can be obtained as shown in FIG. 2D in block 112.

The placement result in phase 1 (block 104 to block 110) can fit the OPP problem more closely and provide better initial solutions. Although the obtained PDS can retain the complete the ability of the observation of this specified spanning tree T, this PDS may not retain the feasibility for the entire power grid G since multiple loops may be involved in the entire power grid G. Thus, in order to ensure the complete the ability of the observation of the entire power grid G, the proposed hybrid algorithm will move to phase 2. In one embodiment of the invention embodied an Artificial Bee Colony algorithm to fine tune the result obtained by the phase 1. The ABC algorithm is used to reduce the number of PMUs in phase 2. The ABC algorithm is inspired by the intelligent foraging behavior of honeybee swarms. All foraging bees are classified into three distinct categories: (i) Employed, (ii) Onlookers, (iii) Scouts. All bees currently exploiting a food source are classified as employed. The employed bees bring loads of nectar from food source to the hive and send the information to onlooker bees, which are waiting in the hive tend to choose a source that appears to be of high quality. The ABC algorithm is then performed to minimize the PMU number and also guarantee the feasibility of the solution derived. In the ABC algorithm, each food source represents a possible solution; that is, the number of food sources equals the number of employed bees.

In the OPP problem, each bee represents a strategy of placement, and a collection of binary values form a set of solutions to express which positions are with (given value 1) or without (given value 0) PMUs installed. For example, the solution vector (01100010001000) represents buses 2, 3, 7 and 11 are with PMUs installed, and the dimension d of the solution is 14.

In block 114, inputting the PDS data and enter to Phase 2. In one embodiment, loading the data which obtained from Phase 1 and setting the cycle parameter as 1. In block 116, initializing the parameters and obtain the initial population Xh obtained from phase 1. In block 118, evaluating the fitness function fiti by the following equation:

$${fit}_{i} = \{ \begin{matrix}1 \text{/} \vert {f}_{i} \vert + 1 , {f}_{i} < 0 \\ {f}_{i} , {f}_{i} \geq 0\end{matrix} .$$

Wherein, fi represents the objective value of ith solution.

In block 120, generating a new population in the neighborhood of employed bees via the equation: Vᵢⱼ=Xᵢⱼ+μ(Xᵢⱼ−Xₖⱼ). Wherein, Xij (or Vij) denotes the jth element of Xi (or Vi), and j is a random index from the index set {1, 2, . . . , d}. Xk denotes another solution selected at random from the population, and u is a random number normally distributing in [−1, 1].

In block 122, evaluating the fitness function for each Vi by the equation:

$${fit}_{i} = \{ \begin{matrix}1 \text{/} \vert {f}_{i} \vert + 1 , {f}_{i} < 0 \\ {f}_{i} , {f}_{i} \geq 0\end{matrix} .$$

In block 124, calculating probabilities Ph by equation

$${P}_{h} = {fit}_{i} \text{/} {\sum }_{j = 1}^{SN} {fit}_{i}$$

according to the fitness function fiti obtained from the block 122, and assign onlooker bees according to the probabilities. In block 126, generating a new solution for the onlooker bees via the equation Vᵢⱼ=Xᵢⱼ+μ(Xᵢⱼ−Xₖⱼ). In block 128, re-calculating the fitness function via the equation

$${fit}_{i} = \{ \begin{matrix}1 \text{/} \vert {f}_{i} \vert + 1 , {f}_{i} < 0 \\ {f}_{i} , {f}_{i} \geq 0\end{matrix} .$$

In block 130, apply a greedy search process to find out a best solution.

In block 132, to determine the current solution should be abandoned or not by the equation limit=SN*d. In one embodiment, if the current solution should be abandoned, generates a new randomly solution for the scout bees via the equation Xₕ^{j}=Xₘᵢₙ^{j}+rand[1,0](Xₘₐₓ^{j}−Xₘᵢₙ^{j}). In block 134, the flowchart will be finished if the power network G is completely observed from block 102 to the block 132, or the count value of the parameter cycle is equal to the maximum amount. Otherwise, the flowchart will repeat the block 118 to the block 132 until the power grid G is completely observed or the parameter cycle is equal to the maximum amount.

TABLE 1 to TABLE 6 are illustrate the result in accordance with an embodiment of the present invention. The zero injection nodes of each test system are shown in Table 1.

TABLE 1

| System | Node# | Position |
|---|---|---|
| IEEE 14 | 1 | 7 |
| IEEE 57 | 15 | 4, 7, 11, 21, 22, 24, 26, 34, 36, 37, |
| | | 39, 40, 45, 46, 48 |
| IEEE 118 | 10 | 5, 9, 30, 37, 38, 63, 64, 68, 71, 81 |

Phase 1 provided an initial coarse placement by using 4, 14 and 32 PMUs for the IEEE 14, 57 and 118-bus test systems, respectively, as shown in Table 2.

TABLE 2

| System | Node# | Position | Feasibility |
|---|---|---|---|
| IEEE 14 | 4 | 2, 4, 10, 13 | V |
| IEEE 57 | 14 | 1, 4, 13, 14, 20, 14, 29, 31, 32, 38, | V |
| | | 44, 51, 54, 56 | |
| IEEE 118 | 32 | 3, 10, 11, 12, 19, 22, 27, 30, 31, 32, | V |
| | | 34, 37, 42, 45, 49, 53, 56, 59, 66, 70, | |
| | | 71, 76, 77, 80, 85, 86, 89, 92, 94, 100, | |
| | | 105, 110 | |

Next, phase 2 took relatively fewer iterations to considerably reduce the number of PMUs required to 3, 11 and 28 in Table 3. This phase also guarantees the complete ability of the observation and provides several feasible solutions. That is, phase 2 not only reduces the number of PMUs from phase 1, but also guarantees the feasibility. Note that the variation of iterations depended on the quality of initial placements from phase 1 results.

TABLE 3

| System | Node# | Position |
|---|---|---|
| IEEE 14 | 3 | 2, 6, 9 |
| IEEE 57 | 11 | 1, 4, 13, 20, 25, 29, 32, 38, 51, 54, 56 |
| IEEE 118 | 28 | 1, 8, 11, 12, 17, 21, 27, 29, 32, 34, 37, 42, 45, 49, |
| | | 53, 56, 62, 72, 75, 77, 80, 85, 87, 90, 94, 101, 105, |
| | | 110 |
| | | 3, 9, 11, 12, 17, 21, 23, 28, 34, 37, 40, 45, 49, 52, |
| | | 56, 62, 72, 75, 77, 80, 85, 86, 90, 94, 101, 105, |
| | | 110, 115 |
| | | 3, 10, 11, 12, 17, 20, 23, 29, 34, 37, 41, 45, 49, |
| | | 53, 56, 62, 72, 75, 77, 80, 85, 87, 90, 94, 101, 105, |
| | | 110, 115 |

For each IEEE test system, the number of PMUs derived by the hybrid algorithm meets the currently best results in the literature. In order to further investigate the effects of zero injection buses on the proposed hybrid algorithm, simulations of IEEE test systems with more zero injection buses will be performed. Table 4 depicts the positions of more zero injection buses in various IEEE test systems.

TABLE 4

| System | Node# | Position |
|---|---|---|
| IEEE 14 | 8 | 2, 4, 5, 7, 9, 10, 13, 14 |
| IEEE 57 | 46 | 1, 2, 3, 4, 6, 7, 9, 10, 11, 13, 14, 15, 16, 18, 19, |
| | | 20, 21, 22, 24, 25, 26, 27, 28, 29, 30, 31, 32, 34, |
| | | 35, 36, 37, 39, 40, 44, 45, 46, 47, 48, 49, 50, 51, |
| | | 52, 53, 54, 55, 57 |
| IEEE 118 | 67 | 2, 3, 4, 5, 7, 9, 11, 13, 15, 17, 18, 20, 21, 22, 23, |
| | | 24, 25, 26, 27, 29, 30, 31, 34, 36, 37, 38, 42, 43, |
| | | 44, 45, 47, 48, 49, 51, 52, 53, 54, 56, 57, 61, 62, |
| | | 63, 64, 65, 66, 68, 69, 71, 72, 77, 78, 80, 81, 82, |
| | | 83, 86, 89, 90, 93, 95, 97, 99, 101, 105, 108, 109, |
| | | 115 |

The result of phase 1 presents an initial solution of the PMU placement, which uses 2, 4 and 8 PMUs, respectively in Table 5. Note that the result of phase 1 may not retain feasibility for the systems; for example, the IEEE 118-bus test system.

TABLE 5

| System | Node# | Position | Feasibility |
|---|---|---|---|
| IEEE 14 | 2 | 4, 13 | V |
| IEEE 57 | 4 | 1, 9, 24, 56 | V |
| IEEE 118 | 8 | 12, 32, 49, 59, 75, 85, 100, 110 | X |

After performing phase 2, Table 6 shows that the number of PMUs can be reduced to 3 in the IEEE 57-bus test system, and the refined solution derived in phase 2 can achieve the complete ability of ability of the observation. Moreover, the number of iterations required in phase 2 is quite small, since phase 1 apparently provides good results as initial solutions for phase 2. In conclusion, it can be observed that if more zero injection buses are contained in the power grid, the number of the PMU required for solving the OPP will be reduced.

TABLE 6

| System | Node# | Position |
|---|---|---|
| IEEE 14 | 2 | (4, 13), (1, 6), (3, 9), (5, 14), (5, 9), (5, 12), |
| | | (1, 11), (5, 6) |
| IEEE 57 | 3 | (8, 12, 56), (12, 29, 56), (6, 12, 56) |
| IEEE 118 | 8 | (12, 32, 37, 59, 75, 85, 100, 110) |
| | | (12, 32, 39, 59, 75, 85, 100, 110) |
| | | (12, 32, 40, 59, 75, 85, 100, 110) |
| | | (12, 32, 41, 59, 75, 85, 100, 110) |
| | | (12, 32, 42, 59, 75, 85, 100, 110) |

Aforementioned, the invention can minimize the number of PMUs in order to solve the OPP issue and to ensure the complete ability of the observation of the entire power grid simultaneously.

While the foregoing description and drawings represent embodiments of the present invention, it will be understood that various additions, modifications and substitutions may be made therein without departing from the spirit and scope of the principles of the present invention. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, and not limited to the foregoing description.

What is claimed is:

1. A method for optimizing replacement of phasor measurement unit, comprising:
calculating a degree of a plurality of nodes of a power system;
selecting a node with a maximum degree as a center, and propagating through adjacent nodes from said center to form a spanning tree;
finding a feasible power dominating set of minimum cardinality for said spanning tree;
evaluating a fitness function by a equation
$${fit}_{i} = \{ \begin{matrix}1 \text{/} \vert {f}_{i} \vert + 1 , {f}_{i} < 0 \\ {f}_{i} , {f}_{i} \geq 0\end{matrix}$$
according to said feasible power dominating set;
generating a solution by a equation Vᵢⱼ=ᵢⱼ+μ(Xᵢⱼ−Xₖⱼ);
calculating a probability by a equation
$${P}_{h} = {fit}_{i} \text{/} {\sum }_{j = 1}^{SN} {fit}_{i} ;$$
and
selecting a best solution based on said probability via a greedy search.

2. The method as claimed in claim 1, further comprising:
setting a cycle parameter; and
letting a value of said cycle parameter plus one when obtain said best solution or
said solution.

3. The method as claimed in claim 1, further comprising:
stopping the method when said cycle parameter equals to a predetermined maximum value.

4. The method as claimed in claim 1, further comprising:
abandoning a current solution; and
determining said best solution.

5. The method as claimed in claim 4, said abandoning step is determined by calculating the equation limit=SN*d and said best solution is determined randomly by the equation Xₕ^{j}=Xₘᵢₙ^{j}+rand[1,0](Xₘₐₓ^{j}−Xₘᵢₙ^{j}).

6. The method as claimed in claim 1, wherein said fitness function, said probability, and said best solution are obtained by an Artificial Bee Colony algorithm.

7. The method as claimed in claim 6, wherein said method obtained a potential solution through a preliminary calculation, and then fine-tune said potential solution via said Artificial Bee Colony algorithm to obtain said best solution.
